(19) United States
(12) Patent Application Publication
(10) Pub. No.: US 2013/0038345 A1
(43) Pub. Date: Feb. 14, 2013

(54) PROBE STRUCTURE, PROBE APPARATUS, PROBE STRUCTURE MANUFACTURING METHOD, AND TEST APPARATUS

(71) Applicants: Hidenori KITAZUME, Miyagi (JP); Koji ASANO, Saitama (JP)

(72) Inventors: Hidenori KITAZUME, Miyagi (JP); Koji ASANO, Saitama (JP)

(73) Assignee: ADVANTEST CORPORATION, Tokyo (JP)

(21) Appl. No.: 13/612,871

(22) Filed: Sep. 13, 2012

Related U.S. Application Data
(63) Continuation of application No. PCT/JP2011/000923, filed on Feb. 18, 2011.

(30) Foreign Application Priority Data
May 28, 2010 (JP) 2010-122302

(51) Int. Cl. G01R 1/067; G01R 3/00; G01R 1/073

(52) U.S. Cl. 324/755.01; 29/887

(57) ABSTRACT

Probes are arranged precisely and at a narrow pitch. Provided is a probe structure receiving and transmitting an electric signal from/to a device. The probe structure includes a contact point that transmits an electric signal, a probe on which the contact point is formed, a probe pad section that is electrically coupled to the contact point, and an insulating section that is provided on the probe and that insulates a bonding wire connected to the probe pad section from the probe. A probe apparatus, a manufacturing method of a probe structure, and a test apparatus are also provided.

### BACKGROUND

1. Technical Field

The present invention relates to a probe structure, a probe apparatus, a probe structure manufacturing method, and a test apparatus.

2. Related Art

Some test apparatuses for testing a device under test perform testing of devices as they are building in a semiconductor wafer or packaged. Such test apparatus conducts the test by electrically contacting a probe needle to an output/input terminal of a device under test (for example, see Patent Document 1). The above-mentioned Patent Document 1 is Japanese Patent Application Publication 2009-2865.

The test apparatus needs to arrange the probes such that the probes correspond to arrangement of input/output terminals of a device under test. However, when the input/output terminals are densely provided or arranged intricately, the probes have to be arranged at a narrow pitch, and consequently wires that connect the probes electrically with circuit interconnect and that are provided by wire-bonding tend to be twisted. The twisted wires prone to contact the adjacent wires, causing adverse affects. Moreover, it is difficult to arrange and mount the probes precisely at prescribed positions. Furthermore, even when a single probe is broken, the whole of the probe apparatus needs to be replaced.

### SUMMARY

Therefore, it is an object of an aspect of the innovations herein to provide a probe structure, a probe apparatus, a probe structure manufacturing method, and a test apparatus, which are capable of overcoming the above drawbacks accompanying the related art. The above and other objects can be achieved by combinations described in the claims. A first aspect of the innovations may include a probe structure receiving and transmitting an electric signal from/to a device. The probe structure includes a contact point that transmits an electric signal, a probe on which the contact point is formed, a probe pad section that is electrically coupled to the contact point, and an insulating section that is provided on the probe and that insulates a bonding wire connected to the probe pad section from the probe. A probe apparatus, a manufacturing method of a probe structure, and a test apparatus are also provided.

The summary clause does not necessarily describe all necessary features of the embodiments of the present invention. The present invention may also be a sub-combination of the features described above.

### BRIEF DESCRIPTION OF THE DRAWINGS

FIG. 1 illustrates a configuration example of a probe structure 100 according to an embodiment.

FIGS. 2A-2D illustrate a method of manufacturing an insulating portion 160 and a picker adhesion section 170 according to the embodiment.

FIG. 3 illustrates a configuration example of a probe apparatus 300 according to the embodiment.

FIG. 4 illustrates a flow of manufacturing the probe apparatus 300 according to the embodiment.

FIG. 5 illustrates a configuration example of a test apparatus 510 according to the embodiment together with a device under test 500.

### DESCRIPTION OF EXEMPLARY EMBODIMENTS

Hereinafter, an embodiment of the present invention will be described. The embodiment does not limit the invention according to the claims, and all the combinations of the features described in the embodiment are not necessarily essential to means provided by aspects of the invention.

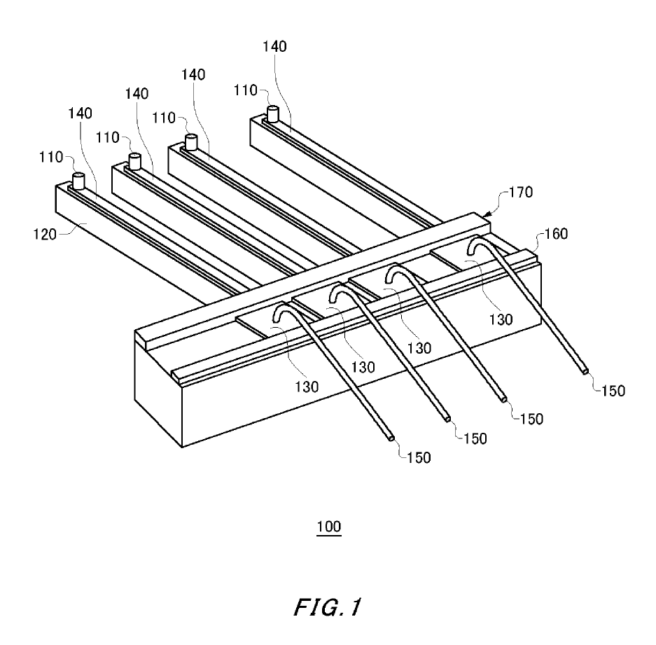

FIG. 1 illustrates a configuration example of a probe structure 100 according to an embodiment of the present invention. The probe structure 100 is electrically connected by wires with a substrate on which the probe structure 100 is mounted. Here, the probe structure 100 is configured such that it is assured that the wires are not twisted and an electric signal is transmitted appropriately. The probe structure 100 includes a contact point 110, a probe 120, a probe pad section 130, a conductive layer 140, an insulating section 160, and a picker attached section 170.

The contact point 110 contacts an input/output terminal of a device under test physically and electrically to transmit an electric signal to the device under test. The contact point 110 may have a hemispherical shape or a needle-like shape with a rounded tip in order to prevent the input/output terminal of the device under test from being damaged or deteriorated. Instead, the contact point 110 may have a flat surface with no protrusion so as to contact the input/output terminal of the device under test with that surface. The contact point 110 may include tungsten, palladium, rhodium, gold, platinum, ruthenium, iridium, and/or nickel.

The contact point 110 is formed on the probe 120. The probe 120 is made from, for example, a silicon wafer. More specifically, the probe 120 may be formed from a semiconductor substrate such as a silicon wafer by using semiconductor fabrication techniques such as photolithography and etching. In this way, the probe 120 can be formed to have a fine structural configuration that corresponds to a pitch of the input/output terminals of the device under test. The probe 120 has, for example, a comb shape. The probe 120 may have the contact point 110 at a tip of each teeth of the comb shape.

The probe pad section 130 is electrically contact with the contact point 110. The probe pad section 130 can be formed by plating the surface of the probe 120. A plurality of the probe pad sections 130 may be provided corresponding to the number of the contact points 110 formed on the probes 120.

The conductive layer 140 electrically connects the contact point 110 and the prove pad section 130. The conductive layer 140 may be formed on the surface of the probe 120 or inside the probe 120. The conductive layer 140 may include tungsten, palladium, rhodium, gold, platinum, ruthenium, iridium, and/or nickel. Moreover, the conductive layer 140 may be formed of the same material as that of the contact point 110.

One end of the bonding wire 150 is bonded to the probe pad section 130 and eclectically connected thereto. The bonding wire 150 may include gold or aluminum. The other end of the boding wire 150 may be connected to a pad on the substrate on which the probe structure 100 is mounted.

The insulating section 160 is provided on the probe 120 and insulates the probe 120 from the bonding wire 150. The insulating section 160 also insulates a plurality of the probes 120 from a plurality of the bonding wires 150 that connected to the plurality of the probe pad sections 130 respectively. The insulating section 160 may be formed on the probe 120 by photolithography. The insulating section 160 may be formed of an insulating resin such as polyimide or a permanent-film resist. The insulating section 160 contacts the bonding wire 150 and tensions it.

The picker attached section 170 is provided so as to enable a picker to stick to the picker attached section, and the picker sticks and holds the probe structure 100 during a manufacturing process. The picker attached section 170 may be provided on the probe 120, and may be formed simultaneously with the insulating section 160. The picker attached section 170 may be formed of substantially the same insulating resin as that of the insulating section 160. The picker attached section 170 may be formed such that it has a larger surface area than that of the conductive layer 140.

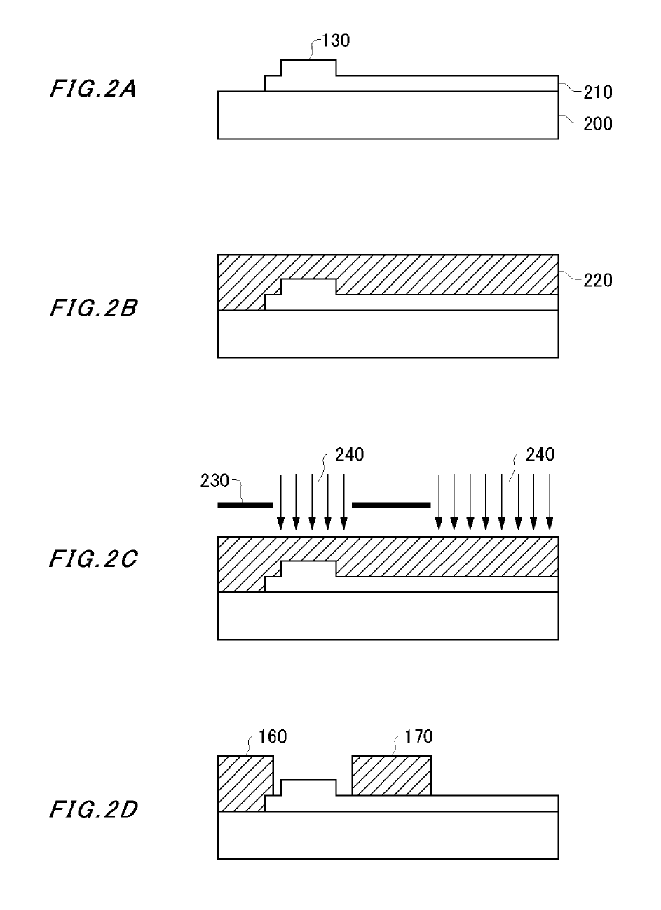

FIG. 2 illustrates a manufacturing method for the insulating section 160 and the picker attached section 170 according to the embodiment. Referring to FIG. 2A, a conductive section 210 including the contact point 110, the probe pad section 130 and the conductive layer 140 is formed on a base substrate 200. The base substrate 200 may be a silicon wafer. For example, the conductive section 210 is formed by deposition in which a material is heated to be evaporated or sublimated and to be then adhered on the surface of the substrate. The probe pad section 130 may be formed by plating the surface of the deposited conductive section 210.

Referring to FIG. 2B, an insulating resin 220 such as polyimide or a permanent resist in a form of liquid is applied on the base substrate 200 on which the conductive section 210 has been formed. Here, the insulating resin 220 can be applied by using a spin-coating method in which the base wafer 200 is fast rotated after the insulating resin 220 is supplied on the base substrate 200 and a thin film is centrifugally formed. Instead, the insulating resin 220 may be applied by spray-coating in which the insulating resin 220 is sprayed and applied. Subsequently, the base substrate 200 is heated and the insulating resin 220 is applied and hardened.

Referring to FIG. 2C, a pattern of a mask 230 is formed on the hardened insulating resin 220 by exposing the resin through the mask 230. The insulating resin 220 is, for example, a solution in which a photo-reactive chemical is dissolved in a solvent. There are two types of such insulating resin 220, one is a “positive type” in which an exposed portion is dissolved, and the other is “a negative type” in which en exposed portion is left. The insulating resin 220 shown in the illustrated example is the positive type, and a portion exposed to light 240 is dissolved.

FIG. 2D illustrates a result of the exposed base substrate 200 which is soaked in a developer and on which unnecessary portions of the insulating resin 220 are removed. In the manner described above, the insulating section 160 and the picker attached section 170 are formed on the base substrate 200.

The base wafer 200 on which the insulating section 160 and the picker attached section 170 have been formed by the above-described manufacturing process is processed to have a probe shape, and the probe structure 100 is obtained. The base wafer 200 may be processed by dry-etching using a gas or wet-etching using a liquid. For instance, the probe structure 100 having a plurality of probe needles may be formed by processing the base substrate 200 so as to have a comb shape.

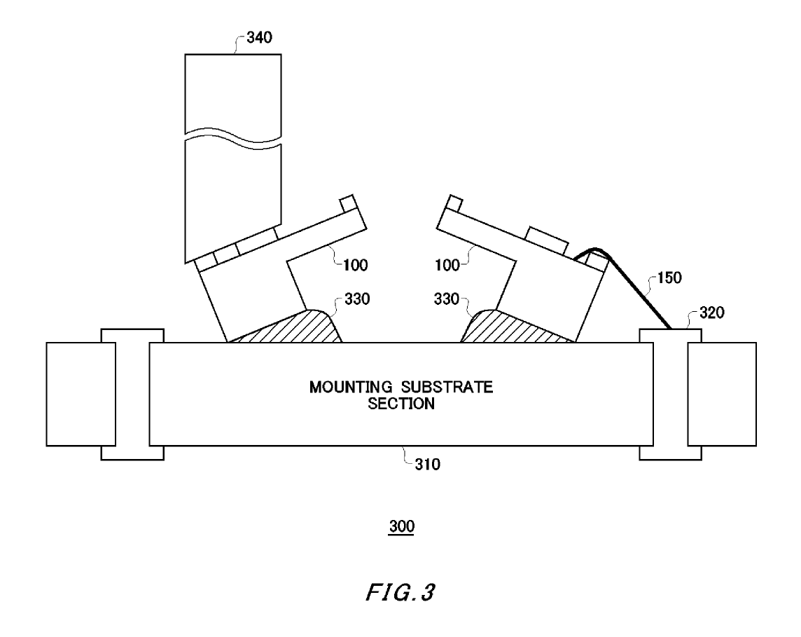

FIG. 3 illustrates a configuration example of a probe apparatus 300 according to the embodiment. The probe apparatus 300 is electrically connected to a device through the contact point 110 provided on the probe structure 100. The probe apparatus 300 includes the probe structure 100, a mounting substrate section 310, and a wiring section 320.

The mounting substrate section 310 mounts one or more probe structures 100. The mounting substrate section 310 is, for example, made of a material with a relatively small coefficient of thermal expansion such as ceramics. The mounting substrate section 310 can be made to have a thickness with which a sufficient strength is secured and a temperature difference between the front face and the back face is minimized. In this way, warpage of the mounting substrate portion 310 due to environmental variation such as temperature change can be prevented. And consequently, the plurality of probes can contact the plurality of the input/output sections of the device at substantially an equal height and with substantially an equal pressure.

The wiring section 320 receives and transmits electric signals from/to the plurality of contact points 110 provided on the probe structure 100. The wiring section 320 may be formed on the surface of the mounting substrate portion 310 on which the probe structure 100 is mounted, and the wiring section 320 may include a pad, a through-via, a connector, a circuit element and the like. The wiring section 320 may be coupled via a through-via or the like to a circuit formed on the back side of the mounting substrate portion 310. The wiring section 320 is electrically connected to the plurality of the probe pad sections 130 on the probe structure 100 through the bonding wires 150.

Here, the bonding wire 150 is tensioned by the insulating section 160 while it is physically in contact with the insulating section 160. One end of the bonding wire 150 is bonded to the probe pad section 130, the bonding wire 150 is bent in a loop with a supporting point which is a point where the insulating section 160 contacts the bonding wire, and then connected to the wiring section 320 on the mounting substrate portion 310. In this manner, the bonding wire 150 physically contacts the insulating section 160, and thereby the bonding wire 150 can be spatially appropriately arranged. As a result, it is possible to prevent the wire from being twisted. More specifically, with such arrangement of the bonding wire 150, even if the probes 120 are formed at a narrow pitch, electric short between the probe 120 and adjacent wires or the like can be prevented.

Here, the insulating section 160 may have elasticity, and a surface of such insulating section 160 may be dented when it contacts the bonding wire 150 and tensions the bonding wire. In this manner, the bonding wire 150 can retain the position where it contacts the insulating section 160, and consequently it is possible to prevent electric short with adjacent wires even when the bonding wires are provided at a narrow pitch.

Here, the probe structure 100 is mounted on the wiring section 320 using an adhesive 330. The adhesive 330 may be an ultraviolet cure adhesive which is cured when irradiated with an ultraviolet beam or the like. The probe structure 100 is adhered to a picker 340 by suction and it is moved onto the mounting substrate portion 310, and then the probe structure 100 is fixed thereon with the adhesive 330. When the probe structure 100 is stuck to the picker 340 at a position with an error, the probe structure 100 is mounted on the mounting substrate portion 310 at a corresponding position with the error.

For example, the surface of the probe structure 100 has a convex-concave portion which is formed by the probe pad section 130 and the conductive layer 140 as illustrated in FIG. 2A. When the probe structure 100 is adhered to the picker 340 by suction as it is, the picker 340 cannot pick the probe structure 100 with a fine positional accuracy because of the convex-concave portion on the surface of the probe structure. Consequently, the probe structure 100 cannot be arranged precisely on the mounting substrate portion 310.

In order to address this, the picker attached section 170 having a larger area than the probe pad section 130 and having a uniform height can be provided on the probe structure 100. With the picker attached section 170, the picker 340 can firmly pick and hold the probe pad section 130 with a fine positional accuracy. In the probe structure 100, the height of the insulating section 160 and the height of the picker attached section 170 are substantially same, and therefore the picker 340 is able to hold the picker attached section as well as the insulating section 160 by suction. When the picker 340 firmly picks the probe pad section 130 with a fine positional accuracy by suction power, the probe structure 100 can be accurately arranged on the mounting substrate portion 310.

As described above, in the probe apparatus 300 according to the embodiment, it is possible to wire-bond the probe pad sections 130 on the probe structure 100 at a narrow pitch and with a fine positional accuracy. Moreover, the probe structure 100 can be accurately arranged on the mounting substrate portion 310. Therefore, even when input/output terminals of a device are densely provided or arranged intricately, it is possible to place the probes 120 at positions corresponding to the arrangement of the input/output terminals in order to make the input/output terminals with the contact points 110 to transmit electric signals.

Although the insulating section 160 and the picker attached section 170 are separately formed in the above-described example, the insulating section 160 and the picker attached section 170 may be formed as a single body on the probe structure 100. In this case, the insulating section 160 may be formed on the surface of the probe structure 100 on which the probe pad 130 is formed such that the insulating section 160 has an opening at least in a part of the insulating section on the probe pad 130 to expose the probe pad section 130. Alternatively, the insulating section 160 may be formed on a surface other than those of the contact point 110 and the probe pad section 130. In this way, the picker 340 can hold a wide area of the insulating section 160 by suction and therefore it is possible to pick the probe structure 100 with a fine positional accuracy.

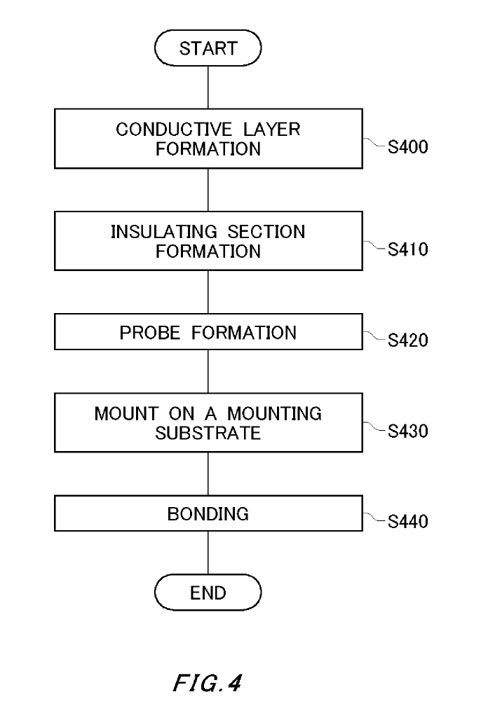

FIG. 4 illustrates a manufacturing flow of the probe apparatus 300 according to the embodiment. Here, the flow until the probe structure 100 is completed in Step S400 is same as above described with reference to FIG. 2. The conductive section 210 is formed on a surface of the base substrate 200 such as a silicon wafer (S400). The conductive section 210 includes the contact point 110, the probe pad 130, and the conductive layer 140, and these members are formed by deposition, plating, or the like.

Subsequently, the insulating section 160 is formed on the conductive section 210 (S410). The base substrate 200 on which the conductive section 210 and the insulating section 160 have been formed is etched in, for example, a comb-shape to obtain the probe 120 (S420). Through the flow described above, the probe structure 100 is formed.

The probe structure 100 is mounted on the mounting substrate portion 310 (S430). The probe structure 100 is picked and moved by the picker 340, and arranged in a prescribed position on the mounting substrate portion 310. Here, the probe structure 100 is arranged on the mounting substrate portion 310 such that it is slanted with an angle of about 10 degrees with respect to the horizontal surface of the mounting substrate portion 310. In this manner, the probe structure 100 has the projected contact point 110 and can be mounted on the mounting substrate portion 310. The probe structure 100 is fixed at the prescribed position with the adhesive 330.

Subsequently, one end of the bonding wire 150 is bonded to the probe pad section 130 on the probe structure 100, and the other end of the bonding wire 150 is bonded to the corresponding wiring section 320 (S440). When the probe structure 100 has a plurality of the probe pad sections 130, each of the bonding wires 150 may be bonded to a corresponding one of the probe pad sections 130 and to a corresponding one of the wiring sections 320. When a plurality of the probe structures 100 are mounted on the mounting substrate section 310, each of the bonding wires 150 may be bonded to a corresponding one of the probe pad sections 130 on the probe structures 100 and to a corresponding one of the wiring sections 320.

Through the above described manufacturing flow, it is possible to manufacture the probe apparatus 300 in which the probe structures 100 are wire-bonded at a narrow pitch and with a fine positional precision. Moreover, when some of the probes are broken in the probe apparatus 300 according to the embodiment, the probe apparatus 300 can be repaired by replacing the broken probe structures.

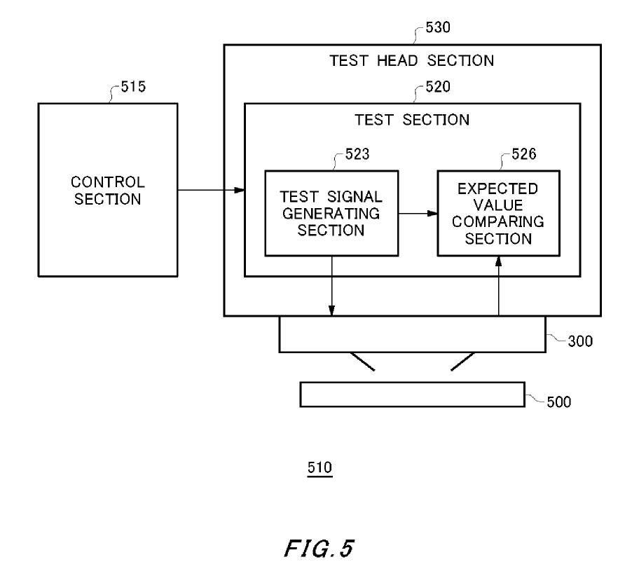

FIG. 5 shows a configuration example of a test apparatus 510 according to the embodiment together with a device under test 500. The test apparatus 510 tests the device under test 500 that includes at least one of an analog circuit, a digital circuit, an analog/digital consolidated circuit, a memory, a system on chip (SOC) and the like. The test apparatus 510 inputs, to the device under test 500, a test signal which depends on test patterns to test the device under test 500, and judges pass or fail of the device under test 500 based on an output signal which is output by the device under test 500 in response to the test signal. The test apparatus 510 includes a control section 515 and a test head section 530.

The control section 515 transmits a control signal to the test head section 530 to conduct the test. The control section 515 also receives test results by the test head section 530 and may store them in a recording device and/or may display them on a display device.

The test head section 530 includes a test section 520. The test section 520 receives and transmits electric signals from/to the device under test 500 to test the device under test 500. The test section 520 includes a test signal generating section 523 and an expected value comparing section 526.

The test signal generating section 523 generates multiple test signals supplied to the device under test 500. The test signal generating section 523 may generate an expected value for a response signal which the test apparatus 500 outputs in response to the test signal. The test signal generating section 523 may be coupled to a plurality of the devices under test 500 through the probe apparatus 300 to test the plurality of devices under test 500.

The expected value comparing section 526 compares a value of received data received by the test head section 530 to an expected value. The expected value comparing section 526 may receive the expected value from the test signal generating section 523. The test apparatus 510 may judge pass or fail of the device under test 500 based on the comparison result generated by the expected value comparing section 526.

The test head section 530 is coupled to the device under test 500 including one or more devices and handles exchange of the test signal between the test apparatus 510 and the device under test 500. The test head section 530 includes the probe apparatus 300 according to the embodiment.

The test apparatus 510 is electrically coupled to the device under test 500 through the probe apparatus 300 according to the embodiment. In this way, the test apparatus 510 can perform test of the device under test 500 that has input/output terminals arranged densely or intricately.

While the embodiment of the present invention has been described, the technical scope of the invention is not limited to the above described embodiment. It is apparent to persons skilled in the art that various alterations and improvements can be added to the above-described embodiment. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A probe structure receiving and transmitting an electric signal from/to a device, comprising:
a contact point that transmits an electric signal;
a probe on which the contact point is formed;
a probe pad section that is electrically coupled to the contact point; and
an insulating section that is provided on the probe and that insulates the probe from a bonding wire connected to the probe pad section.

2. The probe structure according to claim 1, wherein the insulating section is tensioned by contacting the bonding wire.

3. The probe structure according to claim 1, further comprising:
a plurality of the contact points; and
a plurality of the probe pad sections that are each electrically coupled to a corresponding one of the contact points, wherein
the insulating section insulates a plurality of the probes from a plurality of the bonding wires that are each coupled to a corresponding one of the probe pads.

4. The probe structure according to claim 1, wherein one end of the bonding wire is bonded to the probe pad section, and the bonding wire is bent in a loop such that a portion of the bonding wire contacts the insulating section and the portion serves as a supporting point, and the bonding wire is connected to a pad on a substrate on which the probe structure is mounted.

5. The probe structure according to claim 1, wherein the insulating section has a picker attached section where is adhered to a picker that picks and holds the probe structure by suction.

6. The probe structure according to claim 1, wherein the insulating section is formed on a surface of the probe structure on which the probe pad section is formed, such that the insulating section has an opening in at least a part of the insulating section on the probe pad section to expose the probe pad section.

7. The probe structure according to claim 1, wherein the insulating section is insulating resin.

8. The probe structure according to claim 1, wherein the probe is formed from a silicon substrate.

9. The probe structure according to claim 1, wherein the probe is formed to have a comb shape.

10. A probe apparatus electrically connected to a device, comprising:
the probe structure according to claim 1;
a mounting substrate section on which one or more probe structures are mounted; and
a wiring section that receives and transmits electric signals from/to a plurality of contact points provided on the probe structure, wherein
a plurality of probe pad sections provided on the probe structure are electrically coupled to the wiring section through the bonding wire.

11. A method of manufacturing a probe structure that receives and transmits an electric signal from/to a device under test, comprising:
forming a contact point that transmits an electric signal;
forming a probe on which the contact point is formed;
forming a probe pad section that is electrically coupled to the contact point; and
forming an insulating section on the probe, the insulating section insulating a bonding wire connected to the probe pad section from the probe.

12. A test apparatus testing a device under test, comprising:
a test section that receives and transmits an electric signal from/to the device under test to test the device under test; and
the probe apparatus according to claim 10 that is electrically coupled to the device under test.
